(19) United States
(12) Patent Application Publication
(10) Pub. No.: US 2025/0140172 A1
(43) Pub. Date: May 1, 2025

(54) SENSING UNIT AND DISPLAY DEVICE INCLUDING THE SAME

(71) Applicants: Samsung Display Co., Ltd., Yongin-Si (KR); IUCF-HYU (Industry-University Cooperation Foundation Hanyang University), Seoul (KR)

(72) Inventors: Ha Yong JUNG, Yongin-si (KR); Bum Sik KIM, Seoul (KR); Byong Deok CHOI, Seoul (KR); Wook LEE, Yongin-si (KR); Seung Ho PARK, Yongin-si (KR); Sang Jae YEO, Yongin-si (KR); Yong Sang YOO, Seoul (KR); Dong Min LEE, Seoul (KR)

(21) Appl. No.: 18/830,580

(22) Filed: Sep. 11, 2024

(30) Foreign Application Priority Data
Nov. 1, 2023 (KR) 10-2023-0149341

(51) Int. Cl. G09G 3/32; G09G 3/3275

(52) U.S. Cl. CPC G09G 3/32; G09G 3/3275; G09G 2310/0275; G09G 2310/08; G09G 2360/148

(57) ABSTRACT

According to embodiments of the disclosure, a sensing unit includes a sensing line receiving a pixel current from a pixel, a current sink unit connected to the sensing line and receiving a sink current from the sensing line, and a current integrator connected to the sensing line and generating an output voltage using a control current supplied from the sensing line, and the current sink unit changes a current amount of the sink current in response to the output voltage.

This application claims priority to Korean Patent Application No. 10-2023-0149341, filed on Nov. 1, 2023, and all the benefits accruing therefrom under 35 U.S.C. § 119, the content of which in its entirety is herein incorporated by reference.

### BACKGROUND

### 1. Field

The disclosure relates to a sensing unit and a display device including the same.

### 2. Description of the Related Art

As information technology develops, importance of a display device, which is a connection medium between a user and information, has been highlighted. In response to this, a use of display devices such as a liquid crystal display device and an organic light emitting display device is increasing.

Pixels of the display device are deteriorated according to a total usage time, a display luminance, and the like, and thus correction of data (grayscale correction) is required. To this end, an external compensation method which receives a predetermined voltage (and/or current) from the pixels and corrects data using the received voltage is being used.

### SUMMARY

An object of the disclosure is to provide a sensing unit and a display device including the same which is capable of generating desired sensing data regardless of a deviation of circuit elements included in the sensing unit.

According to embodiments of the disclosure, a sensing unit includes a sensing line receiving a pixel current from a pixel, a current sink unit connected to the sensing line and receiving a sink current from the sensing line, and a current integrator connected to the sensing line and generating an output voltage using a control current supplied from the sensing line, and the current sink unit changes a current amount of the sink current in response to the output voltage.

According to an embodiment, the control current corresponds to a difference between the pixel current and the sink current.

According to an embodiment, when the pixel current is greater than the sink current, the output voltage decreases, and the current sink unit increases the sink current in response to the output voltage.

According to an embodiment, when the pixel current is less than the sink current, the output voltage increases, and the current sink unit decreases the sink current in response to the output voltage.

According to an embodiment, when the pixel current and the sink current are same, the output voltage maintains a constant voltage.

According to an embodiment, the sensing unit further includes a voltage storage unit storing the output voltage, and an analog to digital converter generating sensing data using the output voltage stored in the voltage storage unit.

According to an embodiment, the voltage storage unit includes an input switch and an output switch connected in series between an output terminal of the current integrator and the analog to digital converter, and a holding capacitor connected between a common terminal of the input switch and the output switch and a ground potential.

According to an embodiment, the current integrator includes an operational amplifier of which an inverting input terminal is connected to the sensing line and of which a non-inverting input terminal receives a voltage of reference power, a feedback capacitor connected between the inverting input terminal and an output terminal of the operational amplifier, and a reset switch connected in parallel with the feedback capacitor between the inverting input terminal and the output terminal of the operational amplifier.

According to an embodiment, the sensing unit further includes a first switch connected between the sensing line and the current integrator, and a second switch connected between a common node between the first switch and the current integrator and the current sink unit.

According to an embodiment, the sensing unit further includes a current source unit connected to the sensing line and configured to supply a source current to the sensing line.

According to an embodiment, the current source unit controls a current amount of the source current in response to the output voltage.

According to an embodiment, the control current corresponds to a value obtained by subtracting the sink current from a sum of the pixel current and the source current.

According to an embodiment of the disclosure, a display device includes pixels connected to scan lines, data lines, and sensing lines, a data driver configured to supply a data signal to the data lines during a display period and supply a reference data signal to the data lines during a sensing period, a sensing unit connected to the sensing lines and configured to generate sensing data during the sensing period, and a timing controller configured to receive input data and control output data supplied to the data driver in response to the sensing data. A sensing channel of the sensing unit includes a current sink unit connected to a sensing line receiving a pixel current from a pixel in response to the reference data signal and receiving a sink current from the sensing line, and a current integrator connected to the sensing line and generating an output voltage using a control current supplied from the sensing line, and the current sink unit changes a current amount of the sink current in response to the output voltage.

According to an embodiment, the control current corresponds to a difference between the pixel current and the sink current.

According to an embodiment, when the pixel current is greater than the sink current, the output voltage decreases, and the current sink unit increases the sink current in response to the output voltage.

According to an embodiment, when the pixel current is less than the sink current, the output voltage increases, and the current sink unit decreases the sink current in response to the output voltage.

According to an embodiment, when the pixel current and the sink current are same, the output voltage maintains a constant voltage.

According to an embodiment, the sensing channel further includes a voltage storage unit storing the output voltage, and an analog to digital converter generating the sensing data using the output voltage stored in the voltage storage unit.

According to an embodiment, the analog to digital converter is connected to a plurality of sensing channels.

According to an embodiment, the voltage storage unit includes an input switch and an output switch connected in series between an output terminal of the current integrator and the analog to digital converter, and a holding capacitor connected between a common terminal of the input switch and the output switch and a ground potential.

According to an embodiment, the current integrator includes an operational amplifier of which an inverting input terminal is connected to the sensing line and of which a non-inverting input terminal receives a voltage of reference power, a feedback capacitor connected between the inverting input terminal and an output terminal of the operational amplifier, and a reset switch connected in parallel with the feedback capacitor between the inverting input terminal and the output terminal of the operational amplifier.

According to an embodiment, the display device further includes a first switch connected between the sensing line and the current integrator, and a second switch connected between a common node between the first switch and the current integrator and the current sink unit.

According to an embodiment, the display device further includes a current source unit connected to the sensing line and configured to supply a source current to the sensing line.

According to an embodiment, the current source unit controls a current amount of the source current in response to the output voltage.

According to an embodiment, the control current corresponds to a value obtained by subtracting the sink current from a sum of the pixel current and the source current.

According to an embodiment of the disclosure, a display device includes a pixel unit including a plurality of pixels, a data driver connected to the pixels through data lines, and a sensing unit connected to the pixels through sensing lines. A sensing channel of the sensing unit includes a current sink unit connected to a sensing line receiving a pixel current from a pixel and receiving a sink current from the sensing line, and a current integrator connected to the sensing line and generating an output voltage using a control current supplied from the sensing line, and the data driver supplies a voltage of a data signal corresponding to an output voltage of the current integrator to the pixel via a data line.

According to an embodiment, the data driver supplies the output voltage as the voltage of the data signal to the data line.

According to an embodiment, the control current corresponds to a difference between the pixel current and the sink current.

According to an embodiment, the pixel current is changed in response to the output voltage of the current integrator.

According to an embodiment, when the pixel current is greater than the sink current, the output voltage decreases, and the pixel current decreases in response to the decrease of the output voltage.

According to an embodiment, when the pixel current is less than the sink current, the output voltage increases, and the pixel current increases in response to the increase of the output voltage.

According to an embodiment, when the pixel current and the sink current are same, the output voltage maintains a constant voltage, and the pixel current is also maintained constant in response to the constant output voltage.

According to an embodiment, the display device further includes an analog to digital converter generating sensing data using the output voltage.

According to an embodiment, the sink current corresponds to a pixel current that is required to flow to the pixel when the pixel is driven at a predetermined grayscale, and the sensing data corresponds to output data of the pixel corresponding to the predetermined grayscale.

According to an embodiment, the display device further includes a timing controller generating output data corresponding to remaining grayscales except for the predetermined grayscale in response to the sensing data.

According to an embodiment, the display device further includes a determiner connected to the analog to digital converter and configured to supply a control signal to the timing controller when the sensing data maintains the same value during a predetermined time.

According to an embodiment, the current integrator includes an operational amplifier of which an inverting input terminal is connected to the sensing line and of which a non-inverting input terminal receives a voltage of reference power, a feedback capacitor connected between the inverting input terminal and an output terminal of the operational amplifier, and a reset switch connected in parallel with the feedback capacitor between the inverting input terminal and the output terminal of the operational amplifier.

According to an embodiment, the display device further includes a first switch connected between the pixel and the current integrator, and a second switch connected between the current integrator and the current sink unit.

According to an embodiment, the data driver includes a signal generator for supplying a data signal to the data line, a buffer connected between the signal generator and the data, a first input switch connected between the buffer and the current integrator, and a second input switch connected between the buffer and the signal generator.

According to an embodiment, the current sink unit includes at least two current sources, and control switches connected between each of the current sources and the sensing line, and turn-on times of the control switches do not overlap.

According to an embodiment, each of the two or more current sources receives the sink current having different current amounts from the sensing line.

According to an embodiment, the display device further includes a digital buffer receiving the output voltage from the current integrator, and a microcontroller for generating sensing data using an output value of the digital buffer, and the data driver generate a voltage of the data signal corresponding to the output voltage using the sensing data.

According to an embodiment, the sink current corresponds to a pixel current that is required to flow to the pixel when the pixel is driven at a predetermined grayscale, and the sensing data corresponds to output data of the pixel corresponding to the predetermined grayscale.

According to an embodiment, the display device further includes a timing controller generating output data corresponding to remaining grayscales except for the predetermined grayscale in response to the sensing data.

According to an embodiment, the display device further includes a determiner connected to the microcontroller and configured to supply a control signal to the timing controller when the sensing data maintains the same value during a predetermined time.

According to an embodiment of the disclosure, a display device includes a pixel, a data driver connected to the pixel through a data line, a timing controller for supplying output data to the data driver in response to compensation data, and a sensing unit connected to the pixel via a sensing line and including a current integrator generating an output voltage using a control current supplied from the pixel, and sensing data generated in response to the output voltage is stored in the timing controller as the compensation data when the output voltage maintains a constant value during a predetermined time.

According to an embodiment, the display device further includes an analog to digital converter generating the sensing data using the output voltage of the current integrator, and a determiner connected to the analog to digital converter and configured to supply a control signal to the timing controller when the sensing data maintains a constant value during the predetermined time.

According to an embodiment, the display device further includes a digital buffer receiving the output voltage from the current integrator, a microcontroller generating the sensing data using an output value of the digital buffer, and a determiner connected to the microcontroller and configured to supply a control signal to the timing controller when the sensing data maintains a constant value during the predetermined time.

Objects of the disclosure are not limited to the object described above, and other technical objects which are not described will be clearly understood by those skilled in the art from the following description.

In accordance with the sensing unit and the display device including the same according to embodiments of the disclosure, desired sensing data may be generated regardless of a deviation of a circuit element. In addition, in embodiments of the disclosure, the sensing data may have a data (or output data) value corresponding to a pixel current that is required to flow to a pixel, and thus reliability of external compensation may be improved.

However, an effect of the disclosure is not limited to the above-described effect, and may be variously expanded within a range that does not deviate from the spirit and scope of the disclosure.

### BRIEF DESCRIPTION OF THE DRAWINGS

The above and other features of the disclosure will become more apparent by describing in further detail embodiments thereof with reference to the accompanying drawings, in which:

FIG. 1 is a diagram illustrating a display device according to an embodiment of the disclosure;

FIG. 2 is a diagram illustrating a pixel according to an embodiment of the disclosure;

FIG. 3 is a diagram illustrating a sensing channel of a sensing unit according to an embodiment of the disclosure;

FIG. 4 is a waveform diagram illustrating a method of driving the sensing channel shown in FIG. 3;

FIG. 5 is a diagram illustrating a simulation result of the sensing unit shown in FIG. 3;

FIG. 6 is a diagram illustrating a sensing channel of a sensing unit according to an embodiment of the disclosure;

FIG. 7 is a diagram illustrating a display device according to an embodiment of the disclosure;

FIG. 8 is a diagram illustrating an embodiment of a sensing channel and a data driver of a sensing unit shown in FIG. 7;

FIG. 9 is a waveform diagram illustrating a method of driving the sensing channel shown in FIG. 8;

FIG. 10 is a diagram illustrating a simulation result of the sensing unit shown in FIG. 8;

FIG. 11 is a diagram illustrating an embodiment of the sensing channel and the data driver of the sensing unit shown in FIG. 7;

FIG. 12 is a diagram illustrating an embodiment of the sensing channel and the data driver of the sensing unit shown in FIG. 7; and

FIG. 13 is a diagram illustrating an embodiment of the sensing channel and the data driver of the sensing unit shown in FIG. 7.

### DETAILED DESCRIPTION OF THE EMBODIMENT

Hereinafter, various embodiments of the disclosure will be described in detail with reference to the accompanying drawings so that those skilled in the art may easily carry out the disclosure. The disclosure may be implemented in various different forms and is not limited to the embodiments described herein.

In order to clearly describe the disclosure, parts that are not related to the description are omitted, and the same or similar elements are denoted by the same reference numerals throughout the specification. Therefore, the above-described reference numerals may be used in other drawings.

In addition, sizes and thicknesses of each component shown in the drawings are arbitrarily shown for convenience of description, and thus the disclosure is not necessarily limited to those shown in the drawings. In the drawings, thicknesses may be exaggerated to clearly express various layers and areas.

In addition, an expression “is the same” in the description may mean “is substantially the same”. That is, the expression “is the same” may be the same enough for those of ordinary skill to understand that it is the same. Other expressions may also be expressions in which “substantially” is omitted.

Some embodiments are described in the accompanying drawings in relation to functional block, unit, and/or module. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interactive individual blocks, units, and/or modules without departing from the scope of the inventive concept. In addition, in some embodiments, the block, unit and/or module may be physically combined into more complex blocks, units, and/or modules without departing from the scope of the inventive concept.

A term “connection” between two configurations may mean that both of an electrical connection and a physical connection are used inclusively, but is not limited thereto. For example, “connection” used based on a circuit diagram may mean an electrical connection, and “connection” used based on a cross-sectional view and a plan view may mean a physical connection.

Although a first, a second, and the like are used to describe various components, these components are not limited by these terms. These terms are used only to distinguish one component from another component. Therefore, a first component described below may be a second component within the technical spirit of the disclosure. The singular expression includes the plural expression unless the context clearly dictates otherwise.

Meanwhile, the disclosure is not limited to the embodiments disclosed below, and may be modified in various forms and may be implemented. In addition, each of the embodiments disclosed below may be implemented alone or in combination with at least one of other embodiments.

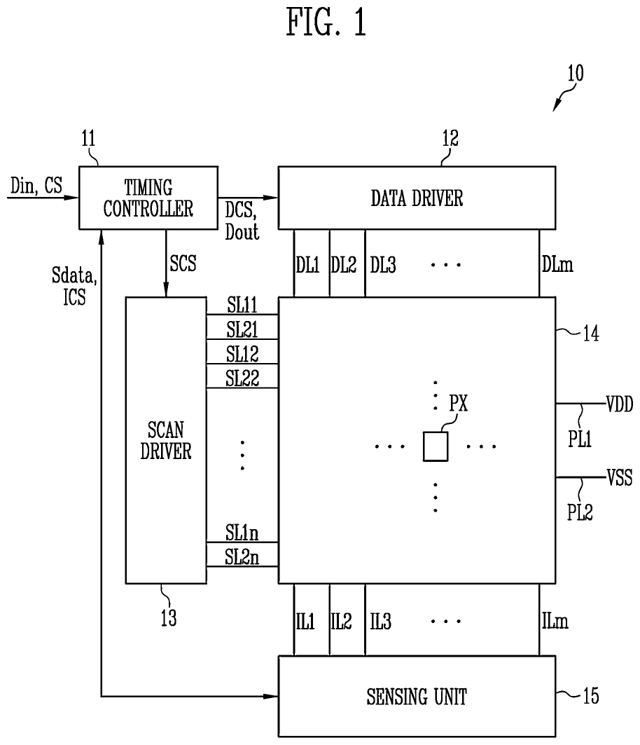

FIG. 1 is a diagram illustrating a display device according to an embodiment of the disclosure.

Referring to FIG. 1, the display device 10 according to an embodiment of the disclosure may include a timing controller 11, a data driver 12, a scan driver 13, a pixel unit 14 (or a display panel), and a sensing unit 15. The above-described configurations may be implemented as separate integrated circuits, and two or more of the above-described configurations may be integrated and implemented as one integrated circuit. In addition, the scan driver 13 may be formed in the pixel unit 14.

The pixel unit 14 may include pixels PX connected to first scan lines SL11, SL12, . . . , and SL1n, second scan lines SL21, SL22, . . . , and SL2n, data lines DL1, DL2, DL3, . . . , and DLm, sensing lines IL1, IL2, IL3, . . . , and ILm, and power lines PL1 and PL2 (here, n and m are natural numbers).

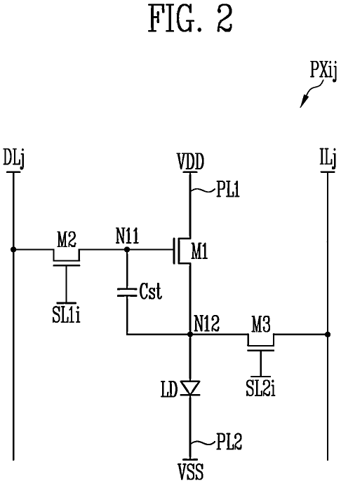

For example, a pixel PXij (refer to FIG. 2) positioned on an i-th horizontal line (or pixel row) and a j-th vertical line (or pixel column) may be connected to an i-th first scan line SL1i, an i-th second scan line SL2i, a j-th data line DLj, and a j-th sensing line ILj (here, i is a natural number less than n, and j is a natural number less than m).

The pixels PX may be driven in two distinct periods such as a display period and a sensing period. The display period may be a period in which a predetermined image is displayed in the pixels PX. The sensing period may be a period in which a characteristic (for example, a threshold voltage and/or mobility) of a driving transistor (or a first transistor M1 shown in FIG. 2) included in each of the pixels PX is sensed.

During the display period, the pixels PX may be selected in a horizontal line unit (for example, pixels PX connected to the scan line may be classified as one horizontal line (or pixel row)) in response to an enable first scan signal supplied to the first scan lines SL11 to SL1n, and the pixels PX selected by the enable first scan signal may receive a data signal from a data line (any one of DL1 to DLm) connected to the selected pixels PX. The pixels PX receiving the data signal may generate light of a predetermined luminance in response to a voltage of the data signal.

During the sensing period, a reference data signal may be supplied to the data lines DL1 to DLm. In addition, during the sensing period, the enable first scan signal may be supplied to at least one scan line (at least one of SL11 to SL1n). The pixels PX receiving the enable first scan signal may supply a pixel current to the sensing lines IL1 to ILm in response to the reference data signal. The sensing unit 15 may generate sensing data Sdata using the pixel current supplied to the sensing lines IL1 to ILm and supply the sensing data Sdata to the timing controller 11.

The scan driver 13 may receive a scan driving signal SCS from the timing controller 11. The scan driving signal SCS may include at least one scan start signal and clock signals required for driving the scan driver 13. The scan driver 13 may generate the enable first scan signal and an enable second scan signal while shifting the scan start signal in response to the clock signal.

For example, the scan driver 13 may sequentially supply the enable first scan signal to the first scan lines SL11 to SL1n and sequentially supply the enable second scan signal to the second scan lines SL21 to SL2n. The scan driver 13 may supply a disable first scan signal when the enable first scan signal is not supplied to the first scan lines SL11 to SL1n. The scan driver 13 may supply the disable second scan signal when the enable second scan signal is not supplied to the second scan lines SL21 to SL2n.

The enable first scan signal and the enable second scan signal may mean a gate-on voltage at which a transistor included in the pixels PX may be turned on. For example, in an N-type transistor, the first enable scan signal and the second enable scan signal may be a high level voltage. The disable first scan signal and the disable second scan signal may mean a gate-off voltage at which the transistor included in the pixels PX may be turned off. For example, in the N-type transistor, the disable first scan signal and the disable second scan signal may be a low level voltage.

In FIG. 1, the first scan lines SL11 to SL1n and the second scan lines SL21 to SL2n are driven by one scan driver 13, but an embodiment of the disclosure is not limited thereto. For example, the respective first scan lines SL11 to SL1n and second scan lines SL21 to SL2n may be driven by different scan drivers.

The data driver 12 may receive output data Dout and a data driving signal DCS from the timing controller 11. The data driving signal DCS may include sampling signals and/or timing signals required for driving the data driver 12. The data driver 12 may generate a data signal based on the data driving signal DCS and the output data Dout.

In an embodiment, during the display period, the data driver 12 may generate the data signal based on the output data Dout and supply the data signal to the data lines DL1 to DLm. In this case, an image corresponding to the output data Dout may be displayed in the pixel unit 14. During the sensing period, the data driver 12 may supply the reference data signal to at least one data line (at least one of DL1 to DLm). The reference data signal may have a preset voltage to sense the characteristic of the driving transistor included in each of the pixels PX.

The timing controller 11 may receive input data Din and a control signal CS from a host system through an interface. For example, the timing controller 11 may receive the input data Din and the control signal CS from at least one of a graphics processing unit (GPU), a central processing unit (CPU), and an application processor (AP) included in the host system. The control signal CS may include various signals including a clock signal.

The timing controller 11 may generate the scan driving signal SCS, the data driving signal DCS, and a sensing driving signal ICS based on the control signal CS. The scan driving signal SCS, the data driving signal DCS, and the sensing driving signal ICS may be supplied to the scan driver 13, the data driver 12, and the sensing unit 15, respectively.

The timing controller 11 may rearrange the input data Din to suit a specification of the display device 10. In addition, the timing controller 11 may correct the input data Din to generate the output data Dout and supply the output data Dout to the data driver 12. For example, the timing controller 11 may generate output data Dout by correcting the input data Din in response to the sensing data Sdata supplied from the sensing unit 15. In this case, the input data Din may be corrected in consideration of the threshold voltage and/or the mobility of the driving transistor included in each of the pixels PX.

The sensing unit 15 may receive the sensing driving signal ICS from the timing controller 11. The sensing driving signal ICS may include a switching control signal for controlling turn-on and turn-off of switches included in the sensing unit 15.

During the display period, the sensing unit 15 may supply a constant voltage (for example, a reference voltage) to the sensing lines IL1 to ILm. During the sensing period, the sensing unit 15 may receive the pixel current from at least one sensing line (at least one of IL1 to ILm).

The sensing unit 15 may include a sensing channel corresponding to each of the sensing lines IL1 to ILm. Each of the sensing channel may receive a sensing data Sdata from any one of the sensing lines (any one of IL1 to ILm), and supply the generated sensing data Sdata to the timing controller 11. The sensing data Sdata may include threshold voltage and/or mobility information of the driving transistor included in each of the pixels PX.

Meanwhile, the sensing channel may be connected to at least two sensing lines (at least two of IL1 to ILm). In this case, the sensing channel may receive at least two pixel currents sequentially (or in a time division manner) during the sensing period, and may sequentially generate the sensing data Sdata in response to the supplied pixel current.

First driving power VDD may be supplied to a first power line PL1, and second driving power VSS may be supplied to a second power line PL2. The first driving power VDD may be power supplying a driving current to the pixels PX. The second driving power VSS may be power receiving the driving current from the pixels PX. During a period in which the pixels PX are set to an emission state, the first driving power VDD may be set to a voltage higher than that of the second driving power VSS. The first power line PL1 and the second power line PL2 may be commonly connected to the pixels PX, but an embodiment of the disclosure is not limited thereto.

In an embodiment, the first power line PL1 may include a plurality of power lines, and the plurality of power lines may be connected to different pixels PX. In an embodiment, the second power line PL2 may include a plurality of power lines, and the plurality of power lines may be connected to different pixels PX. That is, in an embodiment of the disclosure, the pixels PX may be connected to any one the first power line PL1 and any one of the second power line PL2.

FIG. 2 is a diagram illustrating a pixel according to an embodiment of the disclosure. FIG. 2 shows the pixel positioned on the i-th horizontal line and the j-th vertical line.

Referring to FIG. 2, the pixel PXij according to an embodiment of the disclosure may include a light emitting element LD and a pixel circuit for controlling a current amount supplied to the light emitting element LD.

The light emitting element LD may be connected between the first power line PL1 to which the first power VDD is supplied and the second power line PL2 to which the second power VSS is supplied. For example, the first electrode (for example, an anode electrode) of the light emitting element LD may be connected to the first power line PL1 via a second node N12 and a first transistor M1 and a second electrode (for example, a cathode electrode) of the light emitting element LD may be connected to the second power line PL2. The light emitting element LD may emit light with a luminance corresponding to a driving current supplied from the first transistor M1.

The light emitting element LD may be an organic light emitting diode. In addition, the light emitting element LD may be an inorganic light emitting diode such as a micro light emitting diode (LED) or a quantum dot LED. In addition, the light emitting element LD may be an element which includes a mixture of an organic material and an inorganic material. In FIG. 2, the pixel PXij includes a single light emitting element LD, but in another embodiment, the pixel PXij may include a plurality of light emitting elements, and the plurality of light emitting elements may be connected in series, in parallel, or in series-parallel with each other.

The pixel circuit may include the first transistor M1, a second transistor M2, a third transistor M3, and a storage capacitor Cst. In an embodiment, the first transistor M1 to the third transistor M3 may be formed as N-type transistors. However, this is an exemplary, and at least one of the first to third transistors M1 to M3 may be replaced with a P-type transistor.

The first transistor M1 (or a driving transistor) is connected between the first power line PL1 and the second node N12. In addition, a gate electrode of the first transistor M1 is connected to a first node N11. The first transistor M1 controls a current amount supplied from the first power VDD to the second power VSS via the light emitting element LD in response to a voltage of the first node N11.

The second transistor M2 is connected between the data line DLj and the first node N11. In addition, a gate electrode of the second transistor M2 is connected to the first scan line SL1i. The second transistor M2 is turned on when the enable first scan signal is supplied to the first scan line SL1i to electrically connect the data line DLj and the first node N11.

The third transistor M3 is connected between the second node N12 and the sensing line ILj. In addition, a gate electrode of the third transistor M3 is connected to the second scan line SL2i. The third transistor M3 is turned on when the enable second scan signal is supplied to the second scan line SL2i to electrically connect the sensing line ILi and the second node N12.

The storage capacitor Cst is connected between the first node N11 and the second node N12. The storage capacitor Cst stores a voltage corresponding to a difference between the first node N11 and the second node N12.

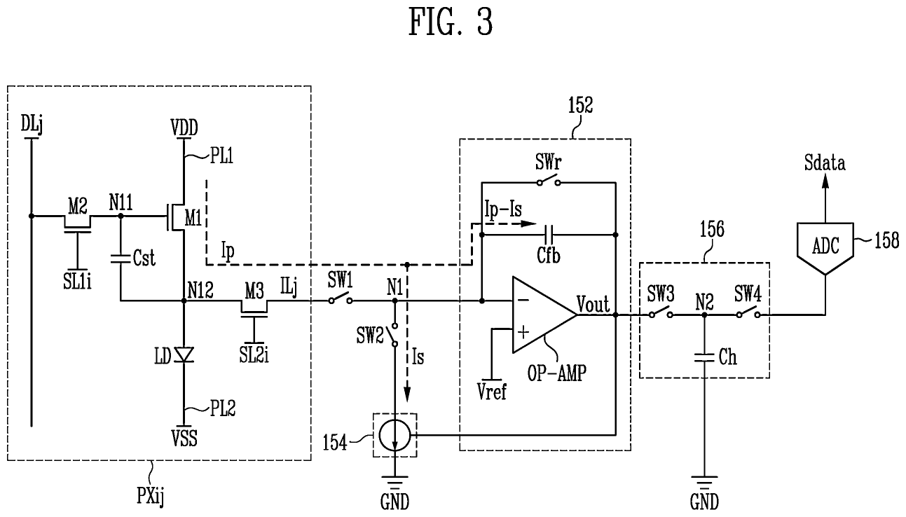

FIG. 3 is a diagram illustrating a sensing channel of a sensing unit according to an embodiment of the disclosure. FIG. 3 shows a sensing channel connected to the j-th sensing line ILj.

Referring to FIG. 3, the sensing channel according to an embodiment of the disclosure may include a current integrator 152, a current sink unit 154, a voltage storage unit 156, and an analog digital converter (hereinafter “ADC”).

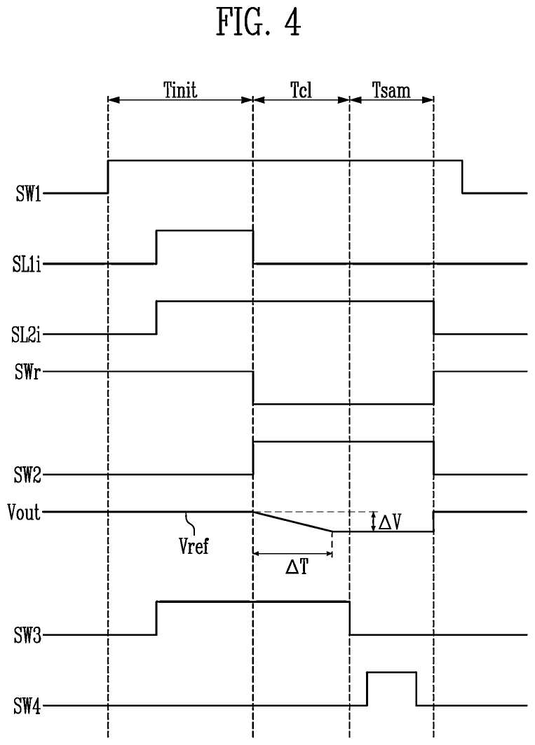

The current integrator 152 controls an output voltage Vout in response to a current amount supplied thereto. A current amount corresponding to a difference between a pixel current Ip and a sink current Is may be supplied to the current integrator 152. A detailed description in relation to this is described later with reference to FIG. 4. The current integrator 152 may include an operational amplifier OP-AMP, a feedback capacitor Cfb, and a reset switch SWr.

The operational amplifier OP-AMP may include an inverting input terminal− connected to the sensing line ILj via a first node N1, a non-inverting input terminal+ receiving reference power Vref, and an output terminal outputting the output voltage Vout.

The feedback capacitor Cfb may be connected between the inverting input terminal− and the output terminal. The feedback capacitor Cfb may accumulate a current amount supplied thereto. The reset switch SWr may be connected in parallel with the feedback capacitor Cfb between the inverting input terminal− and the output terminal. When the reset switch SWr is turned on, the feedback capacitor Cfb may be initialized.

The current sink unit 154 may receive the sink current Is from the sensing line ILj. The current sink unit 154 may control an amount of the sink current Is in response to the output voltage Vout applied to the control terminal of the current sink unit 154. To this end, the current sink unit 154 may be a voltage controlled current source (VCCS).

A first switch SW1 may be connected between the sensing line ILj and the first node N1 (or the inverting input terminal−). The first switch SW1 may maintain a turn-on state in the sensing period. A second switch SW2 may be connected between the first node N1 and the current sink unit 154. The second switch SW2 may be turned on during at least a portion of the sensing period.

The voltage storage unit 156 (or a sampling/hold unit) may temporarily store the output voltage Vout. To this end, the voltage storage unit 156 may include a holding capacitor Ch, a third switch SW3 (or an input switch), and a fourth switch SW4 (or an output switch).

The third switch SW3 may be connected between the output terminal of the operational amplifier OP-AMP and a second node N2. The fourth switch SW4 may be connected between the ADC 158 and the second node N2. The third switch SW3 and the fourth switch SW4 may be turned on and turned off not to overlap each other, for example, the third switch SW3 and the fourth switch SW4 may be turned on and turned off in different timings, during the sensing period to store the output voltage Vout in the holding capacitor Ch, and supply the output voltage Vout stored in the holding capacitor Ch to the ADC 158.

A first electrode of the holding capacitor Ch may be connected to the second node N2, which is a common node of the third switch SW3 and the fourth switch SW4, and a second electrode may be connected to a ground potential GND. The holding capacitor Ch may store the output voltage Vout.

The ADC 158 may change the output voltage Vout stored in the holding capacitor Ch to a digital value. The digital value generated by the ADC 158 may be supplied to the timing controller 11 as the sensing data Sdata. In an embodiment, the ADC 158 may be connected to each sensing channel. In another embodiment, the ADC 158 may be connected to a plurality of sensing channels.

FIG. 4 is a waveform diagram illustrating a method of driving the sensing channel shown in FIG. 3. FIG. 4 may be a one-time sensing waveform for extracting a characteristic value of the pixel PXij during the sensing period.

Referring to FIG. 4, the sensing period may include an initialization period Tinit, a control period Tcl, and a sampling period Tsam.

The initialization period Tinit may be a period in which the feedback capacitor Cfb, the holding capacitor Ch, the sensing line ILj, and the like are initialized to a voltage of the reference power Vref. The control period Tcl may be a period in which the output voltage Vout corresponding to the pixel current Ip is generated. The sampling period Tsam may be a period in which the sensing data Sdata corresponding to the output voltage Vout is generated.

During the sensing period, the first switch SW1 may maintain a turn-on state. When the first switch SW1 is turned on, the sensing line ILj and the first node N1 (that is, the inverting input terminal−) may be electrically connected.

During the initialization period Tinit, the reset switch SWr may be set to a turn-on state. When the reset switch SWr is set to the turn-on state, the operational amplifier OP-AMP may operate as a unit gain buffer of which a gain is 1. Therefore, the voltage of the reference power Vref may be output to an output terminal of the operational amplifier OP-AMP.

When the voltage of the reference power Vref is output to the output terminal of the operational amplifier OP-AMP, both ends of the feedback capacitor Cfb may be set to the voltage of the reference power Vref, and thus the feedback capacitor Cfb may be initialized. Since the first switch SW1 is turned on during the initialization period Tinit, the sensing line ILj may be initialized to the voltage of the reference power Vref. Since the third switch SW3 is turned on during the initialization period Tinit, the voltage of the reference power Vref may be supplied to the second node N2, and thus the holding capacitor Ch may be initialized to the voltage of the reference power Vref.

During the initialization period Tinit, the enable first scan signal may be supplied to the first scan line SL1i, and the enable second scan signal may be supplied to the second scan line SL2i. When the enable first scan signal is supplied, the second transistor M2 may be turned on, and thus the reference data signal may be supplied from the data line DLj to the first node N11. When the enable second scan signal is supplied, the third transistor M3 may be turned on, and thus the voltage of the reference power Vref may be supplied to the second node N12. Therefore, a voltage corresponding to the reference data signal and the reference power Vref may be stored in the storage capacitor Cst during the initialization period Tinit.

Supply of the enable second scan signal may be maintained during the control period Tcl. Therefore, during the control period Tcl, the third transistor M3 may be set to a turn-on state, and the pixel current Ip from the pixel PXij may be supplied to the first node N1 via the sensing line ILj. Here, the pixel current Ip may be a current corresponding to the voltage stored in the storage capacitor Cst (that is, the voltage corresponding to the reference data signal and the reference power Vref).

The second switch SW2 may be turned on during the control period Tcl. When the second switch SW2 is turned on, the current sink unit 154 may be electrically connected to the sensing line ILj via the first node N1. A predetermined sink current Is may flow from the sensing line ILj to the ground GND. In this case, a control current (for example, Ip−Is) corresponding to a difference between the pixel current Ip and the sink current Is may be supplied to the feedback capacitor Cfb.

The reset switch SWr is turned off during the control period Tcl. When the reset switch SWr is turned off, the operational amplifier OP-AMP may be driven as a current integrator. The control current Ip−Is may be supplied to the inverting input terminal− and the feedback capacitor Cfb. When the control current Ip−Is is supplied to the feedback capacitor Cfb, a predetermined voltage may be stored in the feedback capacitor Cfb. A voltage difference across the feedback capacitor Cfb increases as an accumulated current amount increases. Here, due to a characteristic of the operational amplifier OP-AMP, the inverting input terminal− and the non-inverting input terminal+ may be short circuited through a virtual ground, and thus a potential difference therebetween may be 0. Therefore, during the control period Tcl, a potential of the inverting input terminal− may maintain the voltage of the reference power Vref regardless of an increase in a potential difference of the feedback capacitor Cfb. Therefore, a potential of the output terminal of the operational amplifier OP-AMP may decrease in response to a potential difference across the feedback capacitor Cfb.

According to such a principle, during the control period Tcl, the control current Ip−Is may be changed to a voltage value, that is, the output voltage Vout through the feedback capacitor Cfb. Here, as the control current Ip−Is increases, a voltage difference ΔV between the reference voltage Vref and the output voltage Vout may also increase.

Meanwhile, the amount of the sink current Is of the current sink unit 154 may be changed in response to the output voltage Vout. In an embodiment, when the pixel current Ip is greater than the sink current Is (that is, Ip>Is), the output voltage Vout may decrease, and thus the sink current Is may increase.

In an embodiment, when the pixel current Ip is less than the sink current Is (that is, Ip<Is), the output voltage Vout may increase, and thus the sink current Is may decrease. In an embodiment, when the pixel current Ip is equal to the sink current Is (that is, Ip=Is), the output voltage Vout may maintain a constant voltage, and thus the sink current Is may also maintain a constant current value. That is, during the control period Tcl, the sink current Is may become equal to the pixel current Ip and the output voltage Vout may maintain a stable state (or a constant voltage).

Finally, the output voltage Vout may be determined in response to the amount of the pixel current Ip. Therefore, the output voltage Vout may include the threshold voltage information (and/or the mobility) of the first transistor M1. The third switch SW3 maintains a turn-on state during the control period Tcl. Therefore, the output voltage Vout may be stored in the holding capacitor Ch.

The fourth switch SW4 is turned on during the sampling period Tsam. When the fourth switch SW4 is turned on, the output voltage Vout stored in the holding capacitor Ch may be supplied to the ADC 158. The ADC 158 may generate the sensing data Sdata using the output voltage Vout and supply the generated sensing data Sdata to the timing controller 11.

Meanwhile, the above-described output voltage Vout may be determined regardless of a deviation of a circuit element included in the current integrator 152 (for example, the gain of the operational amplifier OP-AMP, or a capacity of the feedback capacitor Cfb). For example, even though the capacitance of the feedback capacitor Cfb changes, only a time ΔT for stabilizing the sensing voltage Vout is changed and a voltage value does not change. Therefore, in an embodiment of the disclosure, the sensing data Sdata may be generated regardless of the deviation of the circuit element included in the sensing unit 15.

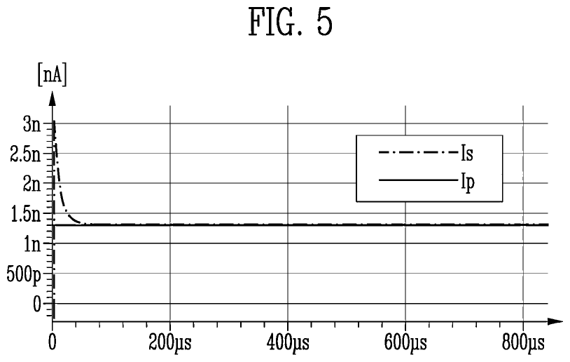

FIG. 5 is a diagram illustrating a simulation result of the sensing unit shown in FIG. 3. In FIG. 5, a Y-axis of a graph represents the pixel current Ip and the sink current Is (for example, nA) and an X-axis represents a time (for example, μs).

Referring to FIG. 5, the sink current Is has a value equal to the pixel current Ip after a predetermined time. Here, a time when the sink current Is has a value approximately 1% compared to the pixel current Ip may be approximately 57.76 μs. That is, in an embodiment of the disclosure, the sink current Is may be set to be similar or equal to the pixel current Ip in a short time, and thus the output voltage Vout may be generated in a short time. Therefore, in an embodiment of the disclosure, the sensing data Sdata may be generated in a state in which the output voltage Vout is stable, and thus reliability of external compensation may be improved.

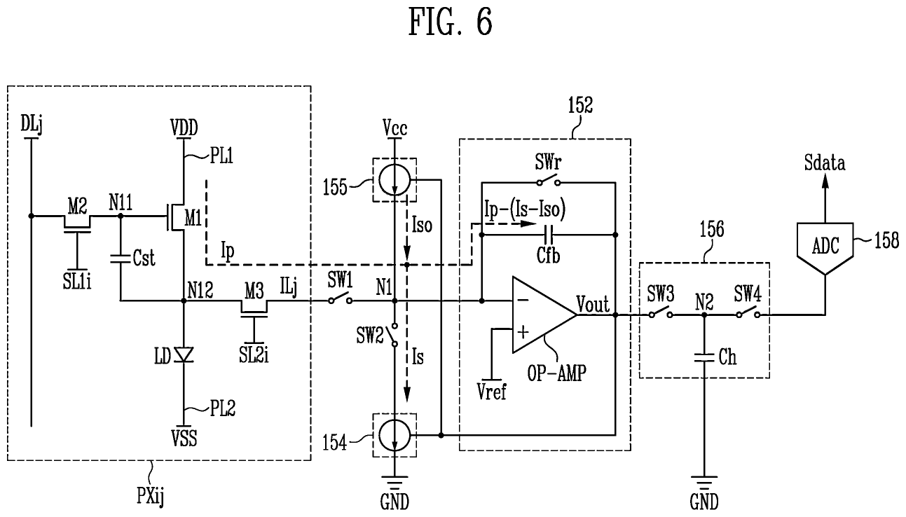

FIG. 6 is a diagram illustrating a sensing channel of a sensing unit according to an embodiment of the disclosure. FIG. 6 shows a sensing channel connected to the j-th sensing line ILj. When describing FIG. 6, descriptions overlapping with FIG. 3 are omitted.

Referring to FIG. 6, the sensing channel according to an embodiment of the disclosure may include the current integrator 152, the current sink unit 154, a current source unit 155, the voltage storage unit 156, and the ADC.

The current source unit 155 may supply a source current Iso to the sensing line ILj. For example, the current source unit 155 may supply the source current Iso to the sensing line ILj. In an embodiment, the current source unit 155 may control a current amount of the source current Iso in response to the output voltage Vout. In an embodiment, an amount of the source current Iso may be different from an amount of the sink current Is.

In this case, the control current supplied to the current integrator 152 during the control period Tcl may be set to Ip−(Is−Iso), and a method driving the sensing channel shown in FIG. 6 may be substantially the same as the method of driving the sensing channel shown in FIG. 3. That is, the sensing channel shown in FIG. 6 may additionally include the current source unit 155 and only additionally control a current amount of the control current supplied to the current integrator 152 using the source current Iso, and a substantial driving method is the same as the sensing channel shown in FIG. 3.

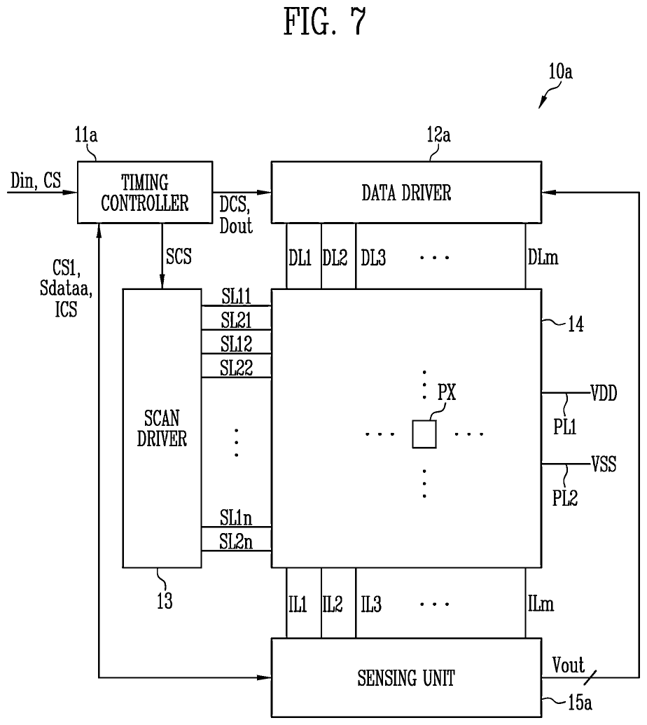

FIG. 7 is a diagram illustrating a display device according to an embodiment of the disclosure. When describing FIG. 7, an overlapping description with FIG. 1 is omitted.

Referring to FIG. 7, the display device 10a according to an embodiment of the disclosure may include a timing controller 11a, a data driver 12a, the scan driver 13, the pixel unit 14 (or the display panel), and a sensing unit 15a. The above-described configurations may be implemented as separate integrated circuits, and two or more of the above-described configurations may be integrated and implemented as one integrated circuit. In addition, the scan driver 13 may be formed in the pixel unit 14.

The data driver 12a may receive the output data Dout and the data driving signal DCS from the timing controller 11a. The data driving signal DCS may include sampling signals and/or timing signals required for driving the data driver 12a. The data driver 12a may generate a data signal based on the data driving signal DCS and the output data Dout.

In an embodiment, during the display period, the data driver 12a may generate the data signal based on the output data Dout and supply the data signal to the data lines DL1 to DLm. In this case, an image corresponding to the output data Dout may be displayed in the pixel unit 14.

In an embodiment, the data driver 12a may supply a reference data signal to at least one data line (at least one of DL1 to DLm) during the sensing period. The reference data signal may be supplied to a specific pixel connected to a specific sensing channel. In addition, during the sensing period, the data driver 12a may receive feedback of the output voltage Vout from at least one specific sensing channel of the sensing unit 15a and supply the fed back output voltage Vout to a specific pixel connected to the specific sensing channel. Here, the fed back output voltage Vout may be a voltage of a data signal corresponding to a predetermined grayscale.

The sensing unit 15a may receive the sensing driving signal ICS from the timing controller 11a. The sensing driving signal ICS may include a switching control signal for controlling turn-on and turn-off of switches included in the sensing unit 15a.

During the display period, the sensing unit 15a may supply a constant voltage (for example, a reference voltage) to the sensing lines IL1 to ILm. During the sensing period, the sensing unit 15a may receive the pixel current from at least one sensing line (at least one of IL1 to ILm). Each of the sensing channels included in the sensing unit 15a may generate the output voltage Vout in response to the pixel current and supply the output voltage Vout to the data driver 12a. In addition, when the output voltage Vout maintains a constant voltage, the sensing unit 15a may change the output voltage Vout to sensing data Sdataa and supply the sensing data Sdataa to the timing controller 11a.

Here, the sensing data Sdataa may be data (or output data Dout) corresponding to a predetermined grayscale in which the threshold voltage and/or mobility information of the driving transistor included in each of the pixels PX is reflected. For example, when the predetermined grayscale is 150 grayscales, the sensing data Sdataa may be the output data Dout to be supplied to the specific pixel PX corresponding to the 150 grayscales.

The timing controller 11a may receive the input data Din and the control signal CS from a host system through an interface. For example, the timing controller 11a may receive the input data Din and the control signal CS from at least one of a graphics processing unit (GPU), a central processing unit (CPU), and an application processor (AP) included in the host system. The control signal CS may include various signals including a clock signal.

The timing controller 11a may generate the scan driving signal SCS, the data driving signal DCS, and the sensing driving signal ICS based on the control signal CS. The scan driving signal SCS, the data driving signal DCS, and the sensing driving signal ICS may be supplied to the scan driver 13, the data driver 12a, and the sensing unit 15a, respectively.

The timing controller 11a may rearrange the input data Din to suit a specification of the display device 10a. In addition, the timing controller 11a may correct the input data Din to generate the output data Dout and supply the output data Dout to the data driver 12a. For example, the timing controller 11a may generate output data Dout by correcting the input data Din in response to the sensing data Sdataa supplied from the sensing unit 15a.

As described above, the sensing data Sdataa may correspond to the output data Dout of the specific pixel corresponding to the predetermined grayscale. The timing controller 11a may generate output data Dout of remaining grayscales to be supplied to the specific pixel using the sensing data Sdataa corresponding to the predetermined grayscale. Thereafter, the timing controller 11a may select the output data Dout corresponding to the grayscale of the input data Din and supply the output data Dout to the data driver 12a. In this case, the output data Dout in which the threshold voltage and/or the mobility of the driving transistor included in each of the pixels PX is compensated may be supplied to the pixels PX.

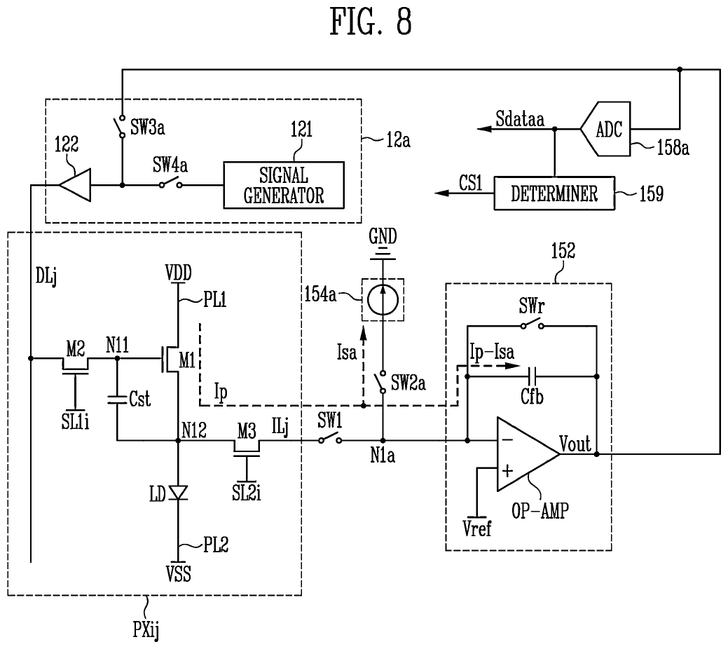

FIG. 8 is a diagram illustrating an embodiment of the sensing channel of the sensing unit shown in FIG. 7 and the data driver. FIG. 8 shows the sensing channel connected to the j-th sensing line ILj.

Referring to FIG. 8, the sensing channel according to an embodiment of the disclosure may include the current integrator 152, a current sink unit 154a, an ADC 158a, and a determiner 159.

The current integrator 152 controls the output voltage Vout in response to the current amount supplied thereto. A current amount corresponding to a difference between the pixel current Ip and a sink current Isa may be supplied to the current integrator 152. The current integrator 152 may include the operational amplifier OP-AMP, the feedback capacitor Cfb, and the reset switch SWr.

The operational amplifier OP-AMP may include an inverting input terminal− connected to the sensing line ILj via a first node N1a, a non-inverting input terminal+ receiving the reference power Vref, and an output terminal outputting the output voltage Vout.

The feedback capacitor Cfb may be connected between the inverting input terminal− and the output terminal of the operational amplifier OP-AMP. The feedback capacitor Cfb may accumulate a current amount supplied thereto. The reset switch SWr may be connected in parallel with the feedback capacitor Cfb between the inverting input terminal− and the output terminal of the operational amplifier OP-AMP. When the reset switch SWr is turned on, the feedback capacitor Cfb may be initialized.

The current sink unit 154a may receive the sink current Isa from the sensing line ILj. Here, the sink current Isa may be set to a constant current value corresponding to a predetermined grayscale. For example, the sink current Isa may be set to a current value corresponding to 150 grayscales.

The first switch SW1 may be connected between the sensing line ILj and the first node N1a (or the inverting input terminal−). The first switch SW1 may maintain a turn-on state in the sensing period. A second switch SW2a may be connected between the first node N1a and the current sink unit 154a. The second switch SW2a may be turned on during at least a portion of the sensing period.

The data driver 12a may include a signal generator 121 and a buffer 122. The buffer 122 may be positioned for each channel of the data driver 12a and may supply the voltage of the data signal and/or the output voltage Vout to the data line DLj connected to the buffer 122. The signal generator 121 may generate a data signal using the output data Dout and supply the data signal to the buffer 122. The signal generator 121 may be connected to a plurality of channels of the data driver 12a.

The data driver 12a may further include a third switch SW3a (or a first input switch) and a fourth switch SW4a (or a second input switch). The third switch SW3a may be connected between an input terminal of the buffer 122 and the output terminal of the operational amplifier OP-AMP. The third switch SW3a may be turned on during at least a portion of the sensing period. The fourth switch SW4a may be connected between the input terminal of the buffer 122 and the signal generator 121. The fourth switch SW4a may be turned on during a portion of the display period and the sensing period. Turn-on periods of the fourth switch SW4a and the third switch SW3a do not overlap.

The ADC 158a may be connected to the output terminal of the operational amplifier OP-AMP. The ADC 158a may change the output voltage Vout to the sensing data Sdataa, which is a digital value.

The determiner 159 may determine whether the sensing data Sdataa output from the ADC 158a is changed. For example, when the sensing data Sdataa output from the ADC 158a is changed, the determiner 159 may determine that desired sensing data Sdataa is not output. For example, when the sensing data Sdataa output from the ADC 158a maintains a constant value during a predetermined time, the determiner 159 may determine that the desired sensing data Sdataa is output. The determiner 159 may include a comparator which compares a current sensing data Sdataa output from the ADC 158a and a previous sensing data Sdataa.

When the desired sensing data Sdataa is output, the determiner 159 may supply a control signal CS1 (for example, a high or low level voltage) corresponding thereto to the timing controller 11a. The timing controller 11a may store the sensing data Sdataa when the control signal CS1 is input and generate the output data Dout using the stored sensing data Sdataa.

Meanwhile, the current sink unit 154a, the ADC 158a, and the determiner 159 may be included in the sensing unit 15a, but the disclosure is not limited thereto. For example, at least one of the current sink unit 154a, the ADC 158a, and the determiner 159a may be included in the data driver 12a.

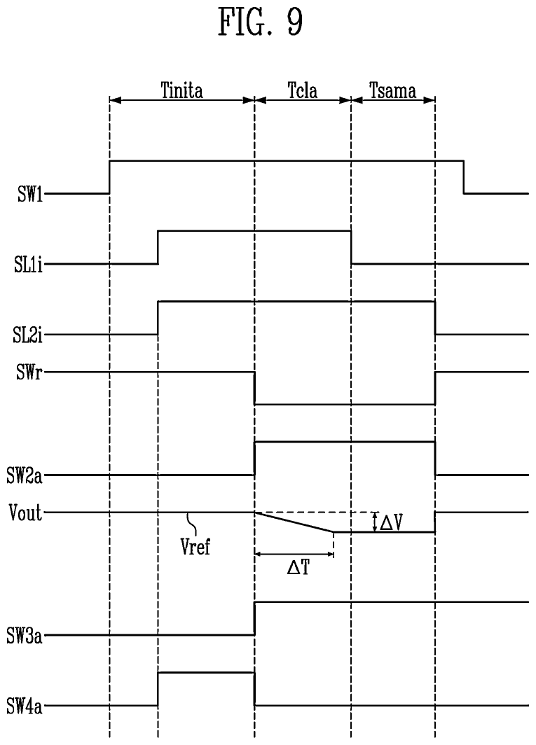

FIG. 9 is a waveform diagram illustrating a method of driving the sensing channel shown in FIG. 8. FIG. 9 may be a one-time sensing waveform for extracting the sensing data Sdataa of the pixel PXij during the sensing period.

Referring to FIG. 9, the sensing period may include an initialization period Tinita, a control period Tcla, and a sampling period Tsama.

The initialization period Tinita may be a period in which a voltage of the reference data signal is stored in the pixel PXij. The initialization period Tinita may be a period in which the feedback capacitor Cfb, the sensing line ILj, and the like are initialized to the voltage of the reference power Vref. The control period Tcla may be a period in which the output voltage Vout corresponding to the pixel current Ip is generated. The sampling period Tsama may be a period in which the sensing data Sdataa corresponding to the output voltage Vout is generated.

During the sensing period, the first switch SW1 may maintain a turn-on state. When the first switch SW1 is turned on, the sensing line ILj and the first node N1a (that is, the inverting input terminal−) may be electrically connected.

During the initialization period Tinita, the reset switch SWr may be set to a turn-on state. When the reset switch SWr is set to the turn-on state, the operational amplifier OP-AMP may operate as a unit gain buffer of which a gain is 1. Therefore, the voltage of the reference power Vref may be output to an output terminal of the operational amplifier OP-AMP.

When the voltage of the reference power Vref is output to the output terminal of the operational amplifier OP-AMP, both ends of the feedback capacitor Cfb may be set to the voltage of the reference power Vref, and thus the feedback capacitor Cfb may be initialized. In addition, since the first switch SW1 is turned on during the initialization period Tinit, the sensing line ILj may be initialized to the voltage of the reference power Vref.

During the initialization period Tinita, the enable first scan signal may be supplied to the first scan line SL1i, and the enable second scan signal may be supplied to the second scan line SL2i. In addition, the fourth switch SW4a may be set to a turn-on state during the initialization period Tinita. When the fourth switch SW4a is turned on, the signal generator 121 may be electrically connected to the data line DLj. During the initialization period Tinita, the signal generator 121 may supply the reference data signal to the data line DLj.

When the enable first scan signal is supplied, the second transistor M2 may be turned on, and thus the reference data signal may be supplied from the data line DLj to the first node N11. When the enable second scan signal is supplied, the third transistor M3 may be turned on, and thus the voltage of the reference power Vref may be supplied to the second node N12. Therefore, a voltage corresponding to the reference data signal and the reference power Vref may be stored in the storage capacitor Cst during the initialization period Tinita.

Supply of the enable first scan signal and the enable second scan signal may be maintained during the control period Tcla. When the enable first scan signal is supplied, the second transistor M2 may be set to a turn-on state during the control period Tcla, and thus the data line DLj may be electrically connected to the first node N11. When the enable second scan signal is supplied, the third transistor M3 may be set to a turn-on state during the control period Tcla, and the pixel current Ip from the pixel PXij may be supplied to the first node N1a via the sensing line ILj. Here, the pixel current Ip may be a current corresponding to the voltage stored in the storage capacitor Cst (that is, the voltage corresponding to the reference data signal and the reference power Vref).

The second switch SW2a may be turned on during the control period Tcla. When the second switch SW2a is turned on, the current sink unit 154a may be electrically connected to the sensing line ILj via the first node N1a. A predetermined sink current Isa may flow from the sensing line ILj to the ground GND. In this case, a control current (for example, Ip−Isa) corresponding to a difference between the pixel current Ip and the sink current Isa may be supplied to the feedback capacitor Cfb. The sink current Isa may be set to a current that is required to flow in the pixel PXij in response to a predetermined grayscale. For example, the sink current Isa may be set to a current that is required to flow in the pixel PXij in response to 150 grayscales.

The third switch SW3a may be turned on during the control period Tcla. When the third switch SW3a is turned on, an input terminal of the buffer 122 and the output terminal of the operational amplifier OP-AMP may be electrically connected.

The reset switch SWr is turned off during the control period Tcla. When the reset switch SWr is turned off, the operational amplifier OP-AMP may be driven as a current integrator. The control current Ip−Isa may be supplied to the inverting input terminal− and the feedback capacitor Cfb. When the control current Ip−Isa is supplied to the feedback capacitor Cfb, a predetermined voltage may be stored in the feedback capacitor Cfb. A voltage difference across the feedback capacitor Cfb increases as an accumulated current amount increases.

Here, due to a characteristic of the operational amplifier OP-AMP, the inverting input terminal− and the non-inverting input terminal+ may be short circuited through a virtual ground, and thus a potential difference therebetween may be 0. Therefore, during the control period Tcla, a potential of the inverting input terminal− may maintain the voltage of the reference power Vref regardless of an increase in a potential difference of the feedback capacitor Cfb. Therefore, a potential of the output terminal of the operational amplifier OP-AMP may decrease in response to a voltage difference across the feedback capacitor Cfb.

According to such a principle, during the control period Tcla, the control current Ip−Isa may be changed to a voltage value, that is, the output voltage Vout through the feedback capacitor Cfb. Here, as the control current Ip−Isa increases, a voltage difference ΔV between the reference voltage Vref and the output voltage Vout may also increase.

Meanwhile, the output voltage Vout is supplied to the data line DLj via the buffer 122. The output voltage Vout supplied to the data line DLj may be supplied to the first node N11 of the pixel PXij, and the pixel PXij may supply the pixel current Ip corresponding to a voltage of the first node N11 to the first node N1a. That is, the pixel current Ip may be changed in response to the output voltage Vout.

In an embodiment, when the pixel current Ip is greater than the sink current Isa (that is, Ip>Isa), the output voltage Vout may decrease. Then, the output voltage Vout supplied to the data line DLj may decrease, and thus the current amount of the pixel current Ip may decrease.

In an embodiment, when the pixel current Ip is less than the sink current Isa (that is, Ip<Isa), the output voltage Vout may increase. Then, the output voltage Vout supplied to the data line DLj may increase, and thus the current amount of the pixel current Ip may increase.

In an embodiment, when the pixel current Ip and the sink current Isa are equal to each other (that is, Ip=Isa), the output voltage Vout may maintain a constant voltage. Then, the output voltage Vout supplied to the data line DLj may maintain a constant voltage, and thus the pixel current Ip may also maintain a constant current amount.

That is, during the control period Tcla, the output voltage Vout may be supplied to the pixel PXij and the pixel current Ip output from the pixel PXij may be changed by the output voltage Vout. In addition, after a certain time ΔT, the pixel current Ip and the sink current Isa may become equal to each other, and in this case, the output voltage Vout may maintain a constant voltage. Here, the output voltage Vout may be set to a voltage corresponding to the sink current Isa (that is, the voltage of the data signal).

In detail, a voltage value of the output voltage Vout is controlled so that the pixel current Ip and the sink current Isa become equal during the control period Tcla. Here, a meaning that the pixel current Ip and the sink current Isa become equal may mean that a current amount of the sink current Isa flows when the output voltage Vout is supplied to the pixel PXij.

In order to implement a predetermined grayscale corresponding to the sink current Isa in the pixel PXij during the display period, a data signal corresponding to the output voltage Vout (that is, a voltage equal to the output voltage) is required to be supplied to the pixel PXij. Here, the output voltage Vout may have a voltage value through which the pixel current Ip corresponding to the sink current Isa flows regardless of a characteristic deviation of the first transistor M1, and thus the characteristic deviation of the first transistor M1 may be compensated.

During the sampling period Tsama, the ADC 158a may generate the sensing data Sdataa using the output voltage Vout supplied from the current integrator 152. The sensing data Sdataa generated by the ADC 158a may be supplied to the timing controller 11a and the determiner 159.

The determiner 159 supplies a control signal CSI to the timing controller 11a when the sensing data Sdataa maintains a constant value. The timing controller 11a stores the sensing data Sdataa when the control signal CS1 is input. Here, the timing controller 11a may set the sensing data Sdataa to the output data Dout of the predetermined grayscale (for example, 150 grayscales). That is, when input data Din corresponding to the predetermined grayscale is input, output data Dout having the same bit value as the sensing data Sdataa may be output. In addition, the timing controller 11a may control values of output data Dout corresponding to remaining grayscales using the sensing data Sdataa corresponding to the predetermined grayscale.

Meanwhile, the ADC 158a may generate the sensing data Sdataa using the output voltage Vout after a certain time ΔT. The certain time ΔT may be experimentally determined in advance, and in this case, the determiner 159 may be removed.

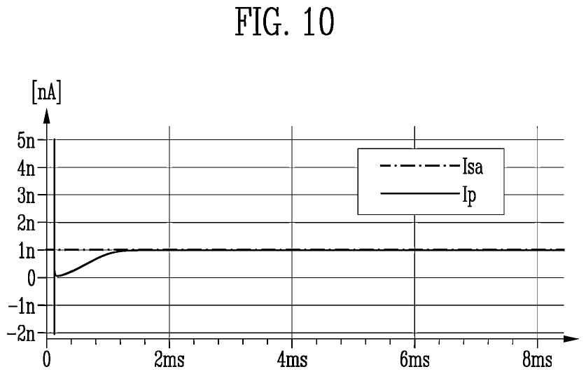

FIG. 10 is a diagram illustrating a simulation result of the sensing unit shown in FIG. 8. In FIG. 10, a Y-axis of a graph represents the pixel current Ip and the sink current Isa (for example, nA) and an X-axis represents a time (for example, ms).

Referring to FIG. 10, during the sensing period, the pixel current Ip may have a value similar or equal to the sink current Isa after a certain time ΔT. For example, the pixel current Ip may become similar or equal to the sink current Isa after approximately 1 ms. In an embodiment of the disclosure, since the sink current Isa is set in response to a grayscale to be expressed, and the sensing data Sdataa is generated using a voltage (that is, the output voltage Vout) at which the pixel current Ip becomes equal to (or similar to) the sink current Isa, reliability of compensation may be improved.

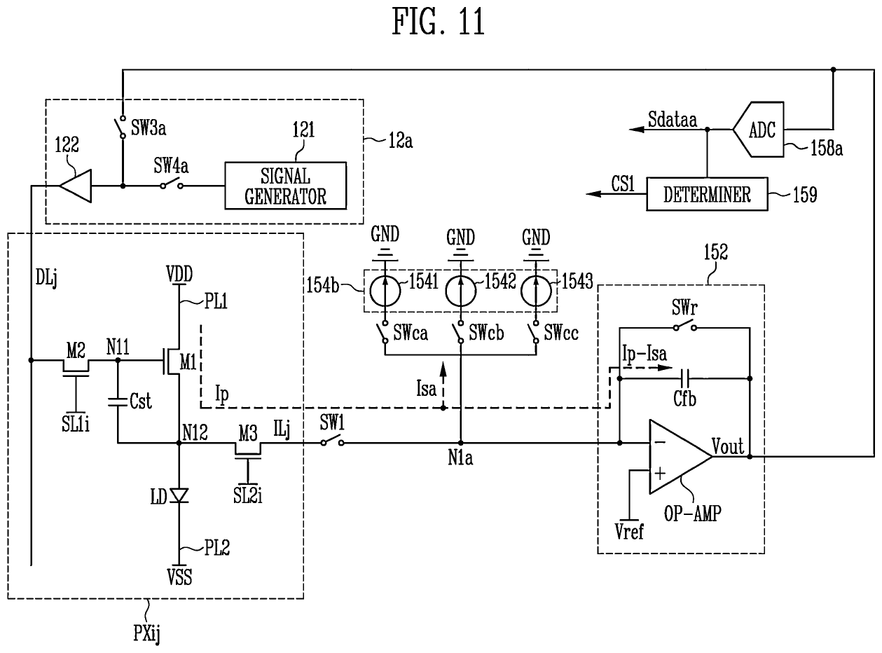

FIG. 11 is a diagram illustrating an embodiment of the sensing channel of the sensing unit shown in FIG. 7 and the data driver. FIG. 11 shows the sensing channel connected to the j-th sensing line ILj. When describing FIG. 11, a description overlapping with FIG. 8 is omitted.

Referring to FIG. 11, the sensing channel according to an embodiment of the disclosure may include the current integrator 152, a current sink unit 154b, the ADC, and the determiner 159.

The current sink unit 154b may include at least two current sources 1541, 1542, and 1543. Each of the plurality of current sources 1541, 1542, and 1543 may receive sink currents Isa having different current amounts from the sensing line ILj.

A control switch (any one of SWca, SWcb, and SWcc) may be connected between each of the current sources 1541, 1542, and 1543 and the first node N1a (or the inverting input terminal−). For example, the first control switch SWca may be connected between the first current source 1541 and the first node N1a, the second control switch SWcb may be connected between the second current source 1542 and the first node N1a, and the third control switch SWcc may be connected between the third current source 1543 and the first node N1a. The control switches SWca, SWcb, and SWcc may be turned on not to overlap each other during the sensing period.

The first current source 1541 may sink a current corresponding to a first predetermined grayscale, the second current source 1542 may sink a current corresponding to a second predetermined grayscale, and the third current source 1543 may sink a current corresponding to a third predetermined grayscale. Here, the first predetermined grayscale, the second predetermined grayscale, and the third predetermined grayscale may be set to different grayscales. For example, the first predetermined grayscale may have a current (that is, pixel current) value that is required to flow in the pixel PXij when implementing 30 grayscales, the second predetermined grayscale may have a current value that is required to flow in the pixel PXij when implementing 100 grayscales, and the third predetermined grayscale may have a current value that is required to flow in the pixel PXij when implementing 180 grayscale.

When the first control switch SWca is turned on, the sink current Isa may be set to a current value corresponding to the first predetermined grayscale, and thus the output voltage Vout may be set to a voltage value corresponding to the first predetermined grayscale. The ADC 158a may supply the sensing data Sdataa generated using the output voltage Vout corresponding to the first predetermined grayscale to the timing controller 11a.

When the second control switch SWcb is turned on, the sink current Isa may be set to a current value corresponding to the second predetermined grayscale, and thus the output voltage Vout may be set to a voltage value corresponding to the second predetermined grayscale. The ADC 158a may supply the sensing data Sdataa generated using the output voltage Vout corresponding to the second predetermined grayscale to the timing controller 11a.

When the third control switch SWcc is turned on, the sink current Isa may be set to a current value corresponding to the third predetermined grayscale, and thus the output voltage Vout may be set to a voltage value corresponding to the third predetermined grayscale. The ADC 158a may supply the sensing data Sdataa generated using the output voltage Vout corresponding to the third predetermined grayscale to the timing controller 11a.

That is, in the sensing channel shown in FIG. 11, the sensing data Sdataa corresponding to a plurality of grayscales may be generated during the sensing period. The timing controller 11a may generate data values corresponding to remaining grayscales using the sensing data Sdataa corresponding to the plurality of grayscales. When generating the data values using the sensing data Sdataa corresponding to the plurality of grayscales, more reliable data values may be generated compared to a case where a data value is generated using the sensing data Sdataa corresponding to one grayscale.

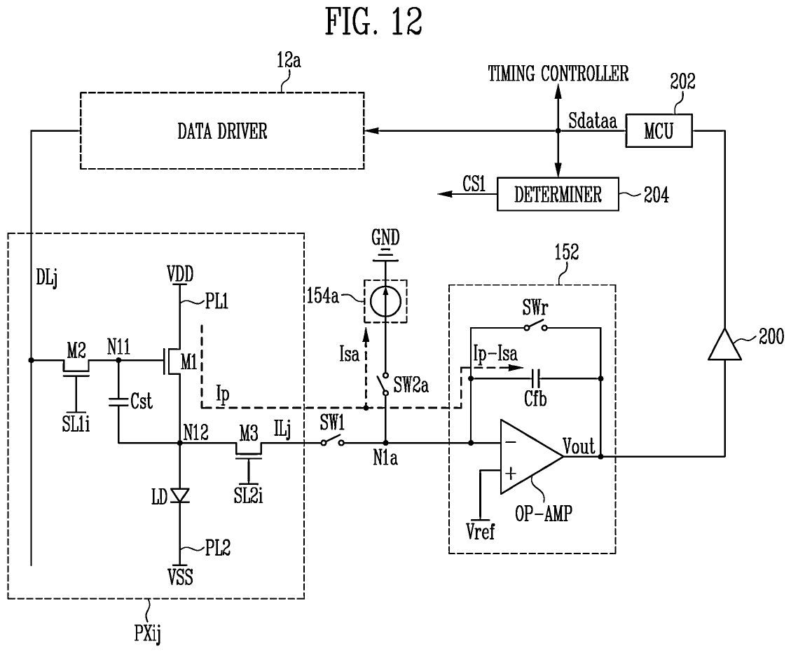

FIG. 12 is a diagram illustrating an embodiment of the sensing channel of the sensing unit shown in FIG. 7 and the data driver. FIG. 12 shows the sensing channel connected to the j-th sensing line ILj. When describing FIG. 12, a description overlapping with FIG. 8 is omitted.

Referring to FIG. 12, the sensing channel according to an embodiment of the disclosure may include the current integrator 152, the current sink unit 154a, a digital buffer 200, a microcontroller (micro controller unit (MCU)) 202, and a determiner 204.

The current integrator 152 controls the output voltage Vout in response to the current amount supplied thereto. A current amount corresponding to a difference between the pixel current Ip and the sink current Isa may be supplied to the current integrator 152. The current integrator 152 may include the operational amplifier OP-AMP, the feedback capacitor Cfb, and the reset switch SWr.

The current sink unit 154a may receive the sink current Isa from the sensing line ILj. Here, the sink current Isa may be set to a constant current value corresponding to a predetermined grayscale. For example, the sink current Isa may be set to a current value corresponding to 150 grayscales. The first switch SW1 may be connected between the sensing line ILj and the first node N1a (or the inverting input terminal−). The second switch SW2a may be connected between the first node N1a and the current sink unit 154a.

The digital buffer 200 may transfer the output voltage Vout to the microcontroller 202.

The microcontroller 202 may generate the sensing data Sdataa using the output voltage Vout supplied from the digital buffer 200. Here, the sensing data Sdataa may be set to a data value corresponding to the sink current Isa. For example, the sensing data Sdataa may be set to the sink current Isa, that is, the output data Dout corresponding to a predetermined grayscale. The sensing data Sdataa generated by the microcontroller 202 may be supplied to the determiner 204, the data driver 12a, and the timing controller 11a.

The data driver 12a changes the sensing data Sdataa supplied from the microcontroller 202 to the data signal or (the voltage of the data signal) and supplies the data signal to the pixel PXij. Then, the pixel PXij may supply the pixel current Ip corresponding to the sensing data Sdataa to the current integrator 152.

The determiner 204 may determine whether the sensing data Sdataa output from the microcontroller is changed. For example, when the sensing data Sdataa output from the microcontroller 202 is continuously changed, the determiner 204 may determine that desired sensing data Sdataa is not output. For example, when the sensing data Sdataa output from the microcontroller 202 maintains a constant value during a predetermined time, the determiner 204 may determine that the desired sensing data Sdataa is output.

When the desired sensing data Sdataa is output, the determiner 204 may supply the control signal CS1 (for example, a high or low level voltage) corresponding thereto to the timing controller 11a. The timing controller 11a may store the supplied sensing data Sdataa when the control signal CS1 is input and generate the output data Dout using the stored sensing data Sdataa.

Meanwhile, the current sink unit 154a, the microcontroller 202, and the determiner 204 may be included in the sensing unit 15a, but the disclosure is not limited thereto. For example, at least one of the current sink unit 154a, the microcontroller 202, and the determiner 204 may be included in the data driver 12a.

Briefly describing an operation process of FIG. 12 in conjunction with FIG. 9, during the initialization period Tinita, the reset switch SWr may be set to a turn-on state, and thus the feedback capacitor Cfb may be initialized. In addition, since the first switch SW1 is turned on during the initialization period Tinita, the sensing line ILj may be initialized to the voltage of the reference power Vref.

During the initialization period Tinita, the enable first scan signal may be supplied to the first scan line SL1i, and the enable second scan signal may be supplied to the second scan line SL2i. During the initialization period Tinita, the data driver 12a may supply the reference data signal to the data line DLj.

When the enable first scan signal is supplied, the second transistor M2 may be turned on, and thus the reference data signal may be supplied from the data line DLj to the first node N11. When the enable second scan signal is supplied, the third transistor M3 may be turned on, and thus the voltage of the reference power Vref may be supplied to the second node N12. Therefore, a voltage corresponding to the reference data signal and the reference power Vref may be stored in the storage capacitor Cst during the initialization period Tinita.

Supply of the enable first scan signal and the enable second scan signal may be maintained during the control period Tcla. When the enable first scan signal is supplied, the second transistor M2 may be a turn-on state during the control period Tcla, and thus the data line DLj may be electrically connected to the first node N11. When the enable second scan signal is supplied, the third transistor M3 may be a turn-on state during the control period Tcla, and the pixel current Ip from the pixel PXij may be supplied to the first node N1a via the sensing line ILj. Here, the pixel current Ip may be a current corresponding to the voltage stored in the storage capacitor Cst (that is, the voltage corresponding to the reference data signal and the reference power Vref).

The second switch SW2a may be turned on during the control period Tcla. When the second switch SW2a is turned on, the current sink unit 154a may be electrically connected to the sensing line ILj via the first node N1a. A predetermined sink current Isa may flow from the sensing line ILj to the ground GND. In this case, a control current (for example, Ip−Isa) corresponding to a difference between the pixel current Ip and the sink current Isa may be supplied to the feedback capacitor Cfb. The sink current Isa may be set to a current that is required to flow in the pixel PXij in response to a predetermined grayscale. For example, the sink current Isa may be set to a current that is required to flow in the pixel PXij in response to 150 grayscales.

The reset switch SWr is turned off during the control period Tcla. When the reset switch SWr is turned off, the operational amplifier OP-AMP may be driven as a current integrator. The control current Ip−Isa may be supplied to the inverting input terminal− and the feedback capacitor Cfb. When the control current Ip−Isa is supplied to the feedback capacitor Cfb, a predetermined voltage may be stored in the feedback capacitor Cfb. A voltage difference across the feedback capacitor Cfb increases as an accumulated current amount increases.

Here, due to a characteristic of the operational amplifier OP-AMP, the inverting input terminal− and the non-inverting input terminal+ may be short circuited through a virtual ground, and thus a potential difference therebetween may be 0. Therefore, during the control period Tcla, a potential of the inverting input terminal− may maintain the voltage of the reference power Vref regardless of an increase in a potential difference of the feedback capacitor Cfb. Therefore, a potential of the output terminal of the operational amplifier OP-AMP may decrease in response to a potential difference across the feedback capacitor Cfb.

According to such a principle, during the control period Tcla, the control current Ip−Isa may be changed to a voltage value, that is, the output voltage Vout through the feedback capacitor Cfb. Here, as the control current Ip−Isa increases, a voltage difference ΔV between the reference voltage Vref and the output voltage Vout may also increase.

Meanwhile, the output voltage Vout may be supplied to the microcontroller 202 via the digital buffer 200. The microcontroller 202 may generate the sensing data Sdataa using the output voltage Vout and supply the sensing data Sdataa to the data driver 12a. The data driver 12a may generate the data signal using the sensing data Sdataa and supply the generated data signal to the data line DLj.

The data signal supplied to the data line DLj may be supplied to the first node N11 of the pixel PXij, and the pixel PXij may supply the pixel current Ip corresponding to a voltage of the first node N11 to the first node N1a. That is, the pixel current Ip may be changed in response to the output voltage Vout.

In an embodiment, when the pixel current Ip is greater than the sink current Isa (that is, Ip>Isa), the output voltage Vout may decrease. Then, the voltage of the data signal supplied from the data driver 12a may decrease in response to the output voltage Vout, and thus the current amount of the pixel current Ip may decrease.

In an embodiment, when the pixel current Ip is less than the sink current Isa (that is, Ip<Isa), the output voltage Vout may increase. Then, the voltage of the data signal supplied from the data driver 12a may increase in response to the output voltage Vout, and thus the current amount of the pixel current Ip may increase.

In an embodiment, when the pixel current Ip and the sink current Isa are equal to each other (that is, Ip=Isa), the output voltage Vout may maintain a constant voltage. Then, the voltage of the data signal supplied from the data driver 12a may maintain a constant voltage, and thus the pixel current Ip may also maintain a constant current amount.

That is, during the control period Tcla, the output voltage Vout is changed to the sensing data Sdataa, and the data driver 12a supplies the data signal corresponding to the sensing data Sdataa to the pixel PXij. Therefore, the pixel current Ip output from the pixel PXij may be changed by the output voltage Vout. In addition, after a certain time ΔT, the pixel current Ip and the sink current Isa may become equal to each other, and in this case, the output voltage Vout may maintain a constant voltage. Here, the output voltage Vout may be set to a voltage corresponding to the sink current Isa.

The microcontroller 202 may generate the sensing data Sdataa using the output voltage Vout. The sensing data Sdataa generated by the microcontroller 202 may be supplied to the timing controller 11a, the determiner 204, and the data driver 12a.

The determiner 204 supplies the control signal CS1 to the timing controller 11a when the sensing data Sdataa maintains a constant value (this period may be the sampling period Tsama). The timing controller 11a stores the sensing data Sdataa when the control signal CS1 is input. Here, the timing controller 11a may set the sensing data Sdataa to the output data Dout of the predetermined grayscale (for example, 150 grayscales). That is, when input data Din corresponding to the predetermined grayscale is input, output data Dout having the same bit value as the sensing data Sdataa may be output. In addition, the timing controller 11a may control values of output data Dout corresponding to remaining grayscales using the sensing data Sdataa corresponding to the predetermined grayscale.

Meanwhile, the timing controller 11a may store the sensing data Sdataa input after a certain time ΔT. The certain time ΔT may be experimentally determined in advance, and in this case, the determiner 204 may be removed.

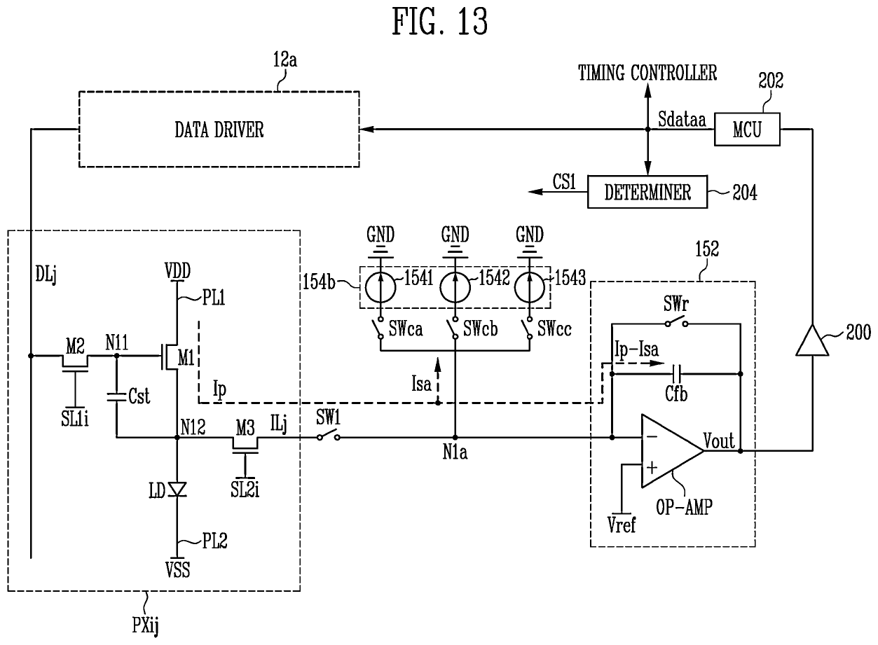

FIG. 13 is a diagram illustrating an embodiment of the sensing channel of the sensing unit shown in FIG. 7 and the data driver. FIG. 13 shows the sensing channel connected to the j-th sensing line ILj. When describing FIG. 13, a description overlapping with FIG. 12 is omitted.

Referring to FIG. 13, the sensing channel according to an embodiment of the disclosure may include the current integrator 152, the current sink unit 154b, a digital buffer 200, the microcontroller 202, and the determiner 204.

The current sink unit 154b may include at least two current sources 1541, 1542, and 1543. Each of the plurality of current sources 1541, 1542, and 1543 may receive sink currents Isa having different current amounts from the sensing line ILj.

A control switch (any one of SWca, SWcb, and SWcc) may be connected between each of the current sources 1541, 1542, and 1543 and the first node N1a (or the inverting input terminal−). For example, the first control switch SWca may be connected between the first current source 1541 and the first node N1a, the second control switch SWcb may be connected between the second current source 1542 and the first node N1a, and the third control switch SWcc may be connected between the third current source 1543 and the first node N1a. The control switches SWca, SWcb, and SWcc may be turned on not to overlap each other during the sensing period.

The first current source 1541 may sink a current corresponding to a first predetermined grayscale, the second current source 1542 may sink a current corresponding to a second predetermined grayscale, and the third current source 1543 may sink a current corresponding to a third predetermined grayscale. Here, the first predetermined grayscale, the second predetermined grayscale, and the third predetermined grayscale may be set to different grayscales. For example, the first predetermined grayscale may have a current (that is, pixel current) value that is required to flow in the pixel PXij when implementing 30 grayscales, the second predetermined grayscale may have a current value that is required to flow in the pixel PXij when implementing 100 grayscales, and the third predetermined grayscale may have a current value that is required to flow in the pixel PXij when implementing 180 grayscale.

When the first control switch SWca is turned on, the sink current Isa may be set to a current value corresponding to the first predetermined grayscale, and thus the output voltage Vout may be set to a voltage value corresponding to the first predetermined grayscale. The microcontroller 202 may supply the sensing data Sdataa generated using the output voltage Vout corresponding to the first predetermined grayscale to the timing controller 11a.

When the second control switch SWcb is turned on, the sink current Isa may be set to a current value corresponding to the second predetermined grayscale, and thus the output voltage Vout may be set to a voltage value corresponding to the second predetermined grayscale. The microcontroller 202 may supply the sensing data Sdataa generated using the output voltage Vout corresponding to the second predetermined grayscale to the timing controller 11a.

When the third control switch SWcc is turned on, the sink current Isa may be set to a current value corresponding to the third predetermined grayscale, and thus the output voltage Vout may be set to a voltage value corresponding to the third predetermined grayscale. The microcontroller 202 may supply the sensing data Sdataa generated using the output voltage Vout corresponding to the third predetermined grayscale to the timing controller 11a.

That is, in the sensing channel shown in FIG. 13, the sensing data Sdataa corresponding to a plurality of grayscales may be generated during the sensing period. The timing controller 11a may generate data values corresponding to remaining grayscales using the sensing data Sdataa corresponding to the plurality of grayscales. When generating the data values using the sensing data Sdataa corresponding to the plurality of grayscales, more reliable data values may be generated compared to a case where a data value is generated using the sensing data Sdataa corresponding to one grayscale.

Although the disclosure has been described with reference to the embodiments of the disclosure, those skilled in the art will understand that the disclosure may be variously corrected and modified within the scope without departing from the spirit and scope of the disclosure described in the claims.

What is claimed is:

1. A sensing unit comprising:
a sensing line receiving a pixel current from a pixel;
a current sink unit connected to the sensing line and receiving a sink current from the sensing line; and
a current integrator connected to the sensing line and generating an output voltage using a control current supplied from the sensing line,
wherein the current sink unit changes a current amount of the sink current in response to the output voltage.

2. The sensing unit according to claim 1, wherein the control current corresponds to a difference between the pixel current and the sink current.

3. The sensing unit according to claim 1, wherein, when the pixel current is greater than the sink current, the output voltage decreases, and the current sink unit increases the sink current in response to the output voltage.

4. The sensing unit according to claim 1, wherein, when the pixel current is less than the sink current, the output voltage increases, and the current sink unit decreases the sink current in response to the output voltage.

5. The sensing unit according to claim 1, wherein, when the pixel current and the sink current are same, the output voltage maintains a constant voltage.

6. The sensing unit according to claim 5, further comprising:
a voltage storage unit storing the output voltage; and
an analog to digital converter generating sensing data using the output voltage stored in the voltage storage unit.

7. The sensing unit according to claim 6, wherein the voltage storage unit comprises:
an input switch and an output switch connected in series between an output terminal of the current integrator and the analog to digital converter; and
a holding capacitor connected between a common terminal of the input switch and the output switch, and a ground potential.

8. The sensing unit according to claim 1, wherein the current integrator comprises:
an operational amplifier of which an inverting input terminal is connected to the sensing line and of which a non-inverting input terminal receives a voltage of reference power;
a feedback capacitor connected between the inverting input terminal and an output terminal of the operational amplifier; and
a reset switch connected in parallel with the feedback capacitor between the inverting input terminal and the output terminal of the operational amplifier.

9. The sensing unit according to claim 1, further comprising:
a first switch connected between the sensing line and the current integrator; and
a second switch connected between a common node between the first switch and the current integrator, and the current sink unit.

10. The sensing unit according to claim 1, further comprising:
a current source unit connected to the sensing line and configured to supply a source current to the sensing line.

11. The sensing unit according to claim 10, wherein the current source unit controls a current amount of the source current in response to the output voltage.

12. The sensing unit according to claim 10, wherein the control current corresponds to a value obtained by subtracting the sink current from a sum of the pixel current and the source current.

13. A display device comprising:
pixels connected to scan lines, data lines, and sensing lines;
a data driver configured to supply a data signal to the data lines during a display period and supply a reference data signal to the data lines during a sensing period;
a sensing unit connected to the sensing lines and configured to generate sensing data during the sensing period; and
a timing controller configured to receive input data and control output data supplied to the data driver in response to the sensing data,
wherein a sensing channel of the sensing unit comprises:
a current sink unit connected to a sensing line receiving a pixel current from a pixel in response to the reference data signal and receiving a sink current from the sensing line; and
a current integrator connected to the sensing line and generating an output voltage using a control current supplied from the sensing line,
wherein the current sink unit changes an amount of the sink current in response to the output voltage.

14. The display device according to claim 13, wherein the control current corresponds to a difference between the pixel current and the sink current.

15. The display device according to claim 13, wherein, when the pixel current is greater than the sink current, the output voltage decreases, and the current sink unit increases the sink current in response to the output voltage.

16. The display device according to claim 13, wherein, when the pixel current is less than the sink current, the output voltage increases, and the current sink unit decreases the sink current in response to the output voltage.

17. The display device according to claim 13, wherein, when the pixel current and the sink current are same, the output voltage maintains a constant voltage.

18. The display device according to claim 17, wherein the sensing channel further comprises:
a voltage storage unit storing the output voltage; and
an analog to digital converter generating the sensing data using the output voltage stored in the voltage storage unit.

19. The display device according to claim 18, wherein the analog to digital converter is connected to a plurality of sensing channels.

20. The display device according to claim 18, wherein the voltage storage unit comprises:
an input switch and an output switch connected in series between an output terminal of the current integrator and the analog to digital converter; and
a holding capacitor connected between a common terminal of the input switch and the output switch, and a ground potential.

21. The display device according to claim 13, wherein the current integrator comprises:
an operational amplifier of which an inverting input terminal is connected to the sensing line and of which a non-inverting input terminal receives a voltage of reference power;
a feedback capacitor connected between the inverting input terminal and an output terminal of the operational amplifier; and
a reset switch connected in parallel with the feedback capacitor between the inverting input terminal and the output terminal of the operational amplifier.

22. The display device according to claim 13, further comprising:
a first switch connected between the sensing line and the current integrator; and
a second switch connected between a common node between the first switch and the current integrator, and the current sink unit.

23. The display device according to claim 13, further comprising:
a current source unit connected to the sensing line and configured to supply a source current to the sensing line.

24. The display device according to claim 23, wherein the current source unit controls a current amount of the source current in response to the output voltage.

25. The display device according to claim 23, wherein the control current corresponds to a value obtained by subtracting the sink current from a sum of the pixel current and the source current.

26. A display device comprising:
a pixel unit including a plurality of pixels;
a data driver connected to the pixels through data lines; and
a sensing unit connected to the pixels through sensing lines,
wherein a sensing channel of the sensing unit comprises:
a current sink unit connected to a sensing line receiving a pixel current from a pixel and receiving a sink current from the sensing line; and
a current integrator connected to the sensing line and generating an output voltage using a control current supplied from the sensing line,
wherein the data driver supplies a voltage of a data signal corresponding to an output voltage of the current integrator to the pixel via a data line.

27. The display device according to claim 26, wherein the data driver supplies the output voltage as the voltage of the data signal to the data line.

28. The display device according to claim 26, wherein the control current corresponds to a difference between the pixel current and the sink current.

29. The display device according to claim 26, wherein the pixel current is changed in response to the output voltage of the current integrator.

30. The display device according to claim 29, wherein, when the pixel current is greater than the sink current, the output voltage decreases, and the pixel current decreases in response to the decrease of the output voltage.

31. The display device according to claim 29, wherein, when the pixel current is less than the sink current, the output voltage increases, and the pixel current increases in response to the increase of the output voltage.

32. The display device according to claim 29, wherein, when the pixel current and the sink current are same, the output voltage maintains a constant voltage, and the pixel current is also maintained constant in response to the constant output voltage.

33. The display device according to claim 26, further comprising:
an analog to digital converter generating sensing data using the output voltage.

34. The display device according to claim 33, wherein the sink current corresponds to a pixel current that is required to flow to the pixel when the pixel is driven at a predetermined grayscale, and
wherein the sensing data corresponds to output data of the pixel corresponding to the predetermined grayscale.

35. The display device according to claim 34, further comprising:
a timing controller generating output data corresponding to remaining grayscales except for the predetermined grayscale in response to the sensing data.

36. The display device according to claim 35, further comprising:
a determiner connected to the analog to digital converter and configured to supply a control signal to the timing controller when the sensing data maintains the same value during a predetermined time.

37. The display device according to claim 26, wherein the current integrator comprises:
an operational amplifier of which an inverting input terminal is connected to the sensing line and of which a non-inverting input terminal receives a voltage of reference power;
a feedback capacitor connected between the inverting input terminal and an output terminal of the operational amplifier; and
a reset switch connected in parallel with the feedback capacitor between the inverting input terminal and the output terminal of the operational amplifier.

38. The display device according to claim 26, further comprising:
a first switch connected between the pixel and the current integrator; and
a second switch connected between the current integrator and the current sink unit.

39. The display device according to claim 26, wherein the data driver comprises:
a signal generator for supplying a data signal to the data line;
a buffer connected between the signal generator and the data line;
a first input switch connected between the buffer and the current integrator; and
a second input switch connected between the buffer and the signal generator.

40. The display device according to claim 26, wherein the current sink unit comprises:
at least two current sources; and
control switches connected between each of the current sources and the sensing line, and
wherein turn-on times of the control switches do not overlap.

41. The display device according to claim 40, wherein each of the two or more current sources receives the sink current having different current amounts from the sensing line.

42. The display device according to claim 26, further comprising:
a digital buffer receiving the output voltage from the current integrator; and
a microcontroller for generating sensing data using an output value of the digital buffer,
wherein the data driver generate a voltage of the data signal corresponding to the output voltage using the sensing data.

43. The display device according to claim 42, wherein the sink current corresponds to a pixel current that is required to flow to the pixel when the pixel is driven at a predetermined grayscale, and
wherein the sensing data corresponds to output data of the pixel corresponding to the predetermined grayscale.

44. The display device according to claim 43, further comprising:
a timing controller generating output data corresponding to remaining grayscales except for the predetermined grayscale in response to the sensing data.

45. The display device according to claim 44, further comprising:
a determiner connected to the microcontroller and configured to supply a control signal to the timing controller when the sensing data maintains the same value during a predetermined time.

46. A display device comprising:
a pixel;
a data driver connected to the pixel through a data line;
a timing controller for supplying output data to the data driver in response to compensation data; and
a sensing unit connected to the pixel via a sensing line and including a current integrator generating an output voltage using a control current supplied from the pixel,
wherein sensing data generated in response to the output voltage is stored in the timing controller as the compensation data when the output voltage maintains a constant value during a predetermined time.

47. The display device according to claim 46, further comprising:
an analog to digital converter generating the sensing data using the output voltage of the current integrator; and
a determiner connected to the analog to digital converter and configured to supply a control signal to the timing controller when the sensing data maintains a constant value during the predetermined time.

48. The display device according to claim 46, further comprising:
a digital buffer receiving the output voltage from the current integrator;
a microcontroller generating the sensing data using an output value of the digital buffer; and
a determiner connected to the microcontroller and configured to supply a control signal to the timing controller when the sensing data maintains a constant value during the predetermined time.
